(19) United States
(12) Patent Application Publication
(10) Pub. No.: US 2017/0024278 A1
(43) Pub. Date: Jan. 26, 2017

(54) METHOD AND APPARATUS FOR ENCODING AND DECODING DATA IN MEMORY SYSTEM

(71) Applicant: Samsung Electronics Co., Ltd., Suwon-si (KR)

(72) Inventors: Moshe TWITTO, Ramat Gan (IL); Jun-Jin KONG, Gyeonggi-do (KR)

(21) Appl. No.: 14/808,505

(22) Filed: Jul. 24, 2015

(51) Int. Cl. G06F 11/10; G11C 29/52

(52) U.S. Cl. CPC G06F 11/1068; G11C 29/52

(57) ABSTRACT

A memory controller of a memory system, the memory system including the memory controller and a memory device, includes a processor configured to receive write data an control the memory controller; and an encoder, the processor being configured to, receive write data, read previously programmed data from a first memory page of a memory cell array of the memory device, and control the encoder to generate encoded data by encoding the write data using stuck bit code (SBC), based on the read previously programmed data, the previously programmed data being data that has been programmed into the first memory page of the memory cell array and has not been erased; the processor being configured to write the encoded data to the first memory page without erasing the first memory page.

### BACKGROUND

1. Field

One or more example embodiments of the inventive concepts relate to methods and apparatuses for encoding and decoding data in a memory system.

2. Related Art

NAND flash memory is composed of erase units (blocks), where each block is composed by several (64, 128 . . . ) pages. For some memory devices, each page may contain several sectors (e.g., 2, 4, or 8). When a sector becomes obsolete (e.g., invalid), resources corresponding to the sector are claimed in a process called garbage collection. In the garbage collection process, a block with the smallest number of valid sectors is chosen, then the valid sectors of the chosen block are copied to one or more other blocks, and the chosen block is erased.

During regular flash maintenance operations in a NAND flash memory device, a sector may be written to several different locations. Because a sector may be written to several different locations, a number of erase operations required may be increased. The average number of physical write operations per logical write operation is called write amplification.

### SUMMARY

Provided are methods and apparatuses for encoding data, programming the encoded data onto an already-programmed memory page without erasing the memory page, and decoding the programmed encoded data.

According to at least one example embodiment of the inventive concepts, a memory controller of a memory system, the memory system including the memory controller and a memory device, includes a processor configured to receive write data an control the memory controller; and an encoder, the processor being configured to, receive write data, read previously programmed data from a first memory page of a memory cell array of the memory device, and control the encoder to generate encoded data by encoding the write data using stuck bit code (SBC), based on the read previously programmed data, the previously programmed data being data that has been programmed into the first memory page of the memory cell array and has not been erased; the processor being configured to write the encoded data to the first memory page without erasing the first memory page.

The processor may be configured such that the first memory page from which the previously programmed data is read is an invalid memory page of the memory cell array.

The processor may be configured to perform a data compression operation on the received write data.

The processor may be further configured to, store an original size, and perform a comparison operation based on a compressed size and the stored original size, wherein the processor is configured to control the encoder to generate the encoded data and to write the encoded data to the first memory page only when the comparison operation indicates the compressed size is less than a threshold size, the original size being a size of the received write data before the data compression operation is performed on the write data, the compressed size being a size of the received write data after the data compression operation is performed on the write data.

The processor may be configured such that, when the comparison operation indicates the compressed size is not less than the threshold size, the processor writes the received write data to a free page of the memory cell array, the free page being a memory page of the memory cell array to which no data has been written since a most recent erase operation performed on the free page.

The processor may be configured to control the encoder such that the encoded data generated by the encoder is different than the received write data and different than the read previously programmed data

The memory controller may further include a decoder, wherein the processor is configured to generate read data by reading data stored in the first page after the encoded data is written to the first page, and the processor is configured to control the decoder to generate decoded data by decoding the read data using SBC.

The decoder may be an error correcting code (ECC) decoder configured to generate the decoded data using SBC and ECC.

The encoder may be an error correcting code (ECC) encoder configured to generate the encoded data using SBC and ECC.

The processor may be configured to read the previously programmed data from the first memory page as single level cell (SLC) data, and the processor may configured to control the encoder to generate the encoded data by encoding the write data using stuck bit code (SBC), based on the read SLC data.

The processor may be configured to read the previously programmed data from the first memory page as multi level cell (MLC) data, and the processor may be configured to control the encoder to generate the encoded data by encoding the write data using stuck bit code (SBC), based on the read MLC data.

According to at least one example embodiment of the inventive concepts, a memory system includes a memory controller; and a memory device; the memory controller being configured to, receive write data, read previously programmed data from a first page of a memory cell array of the memory device, the previously programmed data being data that has been programmed into the first memory page of the memory cell array and has not been erased, generate encoded data by encoding the write data using stuck bit code (SBC), based on the read previously programmed data, and write the encoded data to the first memory page without erasing the first memory page.

The processor may be configured such that the first memory page from which the previously programmed data is read is an invalid memory page of the memory cell array.

The memory controller may be configured to perform a data compression operation on the received write data.

The memory controller may be configured to, store an original size, and perform a comparison operation based on a compressed size and the stored original size, wherein the memory controller is configured to generate the encoded data and to write the encoded data to the first memory page only when the comparison operation indicates the compressed size is less than a threshold size, the original size being a size of the received write data before the data compression operation is performed on the write data, the compressed size being a size of the received write data after the data compression operation is performed on the write data.

The memory controller may be configured such that, when the comparison operation indicates the compressed size is not less than the threshold size, the memory controller writes the received write data to a free page of the memory cell array, the free page being a memory page of the memory cell array to which no data has been written since a most recent erase operation performed on the free page.

The memory controller may be configured to generate the encoded data such that the encoded data is different than the received write data and different than the read previously programmed data.

The memory controller may be further configured to generate read data by reading data stored in the first page after the encoded data is written to the first page, and generate decoded data by decoding the read data using SBC.

The memory controller may be configured to generate the decoded data using SBC and error correcting code (ECC).

The memory controller may be configured to generate the encoded data using SBC and error correcting code (ECC).

The memory controller may be configured to read the previously programmed data from the first memory page as single level cell (SLC) data, and the memory controller may be configured to generate the encoded data by encoding the write data using stuck bit code (SBC), based on the read SLC data.

The memory controller may be configured to read the previously programmed data from the first memory page as multi level cell (MLC) data, and the memory controller may be configured to generate the encoded data by encoding the write data using stuck bit code (SBC), based on the read MLC data.

### BRIEF DESCRIPTION OF THE DRAWINGS

Example embodiments of inventive concepts will be more clearly understood from the following detailed description taken in conjunction with the accompanying drawings in which:

FIG. 1A is a diagram showing a memory system according to at least one example embodiment of the inventive concepts.

FIG. 1B is a diagram for explaining stuck bits with respect to the memory system of FIG. 1A according to at least one example embodiment of the inventive concepts.

FIG. 1C is a flowchart showing a method programming data into an already-programmed memory page according to at least one example embodiment of the inventive concepts.

FIG. 2 is a diagram showing an example of stuck cell information storing units according to at least one example embodiment of the inventive concepts.

FIG. 3 is a schematic block diagram showing the structure of an encoder according to at least one example embodiment of the inventive concepts.

FIG. 4 is a block diagram showing a computer system including a memory system according to example embodiments of inventive concepts.

FIG. 5 is a block diagram showing a memory card according to at least one example embodiment of the inventive concepts.

FIG. 6 is a block diagram showing an example network system including a memory system according to at least one example embodiment of the inventive concepts.

### DETAILED DESCRIPTION OF EXAMPLE EMBODIMENTS

Example embodiments will now be described more fully with reference to the accompanying drawings. Many alternate forms may be embodied and example embodiments should not be construed as limited to example embodiments set forth herein. In the drawings, like reference numerals refer to like elements.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Unless specifically stated otherwise, or as is apparent from the discussion, terms such as “processing” or “computing” or “calculating” or “determining” or “displaying” or the like, refer to the action and processes of a computer system, or similar electronic computing device, that manipulates and transforms data represented as physical, electronic quantities within the computer system's registers and memories into other data similarly represented as physical quantities within the computer system memories or registers or other such information storage, transmission or display devices.

Specific details are provided in the following description to provide a thorough understanding of example embodiments. However, it will be understood by one of ordinary skill in the art that example embodiments may be practiced without these specific details. For example, systems may be shown in block diagrams so as not to obscure the example embodiments in unnecessary detail. In other instances, well-known processes, structures and techniques may be shown without unnecessary detail in order to avoid obscuring example embodiments.

In the following description, illustrative embodiments will be described with reference to acts and symbolic representations of operations (e.g., in the form of flow charts, flow diagrams, data flow diagrams, structure diagrams, block diagrams, etc.) that may be implemented as program modules or functional processes include routines, programs, objects, components, data structures, etc., that perform particular tasks or implement particular abstract data types and may be implemented using existing hardware in existing electronic systems (e.g., nonvolatile memories universal flash memories, universal flash memory controllers, nonvolatile memories and memory controllers, digital point-and-shoot cameras, personal digital assistants (PDAs), smartphones, tablet personal computers (PCs), laptop computers, etc.). Such existing hardware may include one or more Central Processing Units (CPUs), digital signal processors (DSPs), application-specific-integrated-circuits (ASICs), field programmable gate arrays (FPGAs) computers or the like.

Although a flow chart may describe the operations as a sequential process, many of the operations may be performed in parallel, concurrently or simultaneously. In addition, the order of the operations may be re-arranged. A process may be terminated when its operations are completed, but may also have additional steps not included in the figure. A process may correspond to a method, function, procedure, subroutine, subprogram, etc. When a process corresponds to a function, its termination may correspond to a return of the function to the calling function or the main function.

As disclosed herein, the term “storage medium”, “computer readable storage medium” or “non-transitory computer readable storage medium” may represent one or more devices for storing data, including read only memory (ROM), random access memory (RAM), magnetic RAM, core memory, magnetic disk storage mediums, optical storage mediums, flash memory devices and/or other tangible machine readable mediums for storing information. The term “computer-readable medium” may include, but is not limited to, portable or fixed storage devices, optical storage devices, and various other mediums capable of storing, containing or carrying instruction(s) and/or data.

Furthermore, example embodiments may be implemented by hardware, software, firmware, middleware, microcode, hardware description languages, or any combination thereof. When implemented in software, firmware, middleware or microcode, the program code or code segments to perform the necessary tasks may be stored in a machine or computer readable medium such as a computer readable storage medium. When implemented in software, a processor or processors may be programmed to perform the necessary tasks, thereby being transformed into special purpose processor(s) or computer(s).

A code segment may represent a procedure, function, subprogram, program, routine, subroutine, module, software package, class, or any combination of instructions, data structures or program statements. A code segment may be coupled to another code segment or a hardware circuit by passing and/or receiving information, data, arguments, parameters or memory contents. Information, arguments, parameters, data, etc. may be passed, forwarded, or transmitted via any suitable means including memory sharing, message passing, token passing, network transmission, etc.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

Hereinafter, the term entry refers to an element of a matrix or a vector, where an element and an entry of a matrix or a vector have the identical meaning. Furthermore, when AεF^{N×N}, BεF^{N×M}, CεF^{M×N}, and DεF^{M×M}, the following equation may be established:

$$U = [ \begin{matrix}A & B \\ C & D\end{matrix} ] = [ A , B ; C , D ] .$$

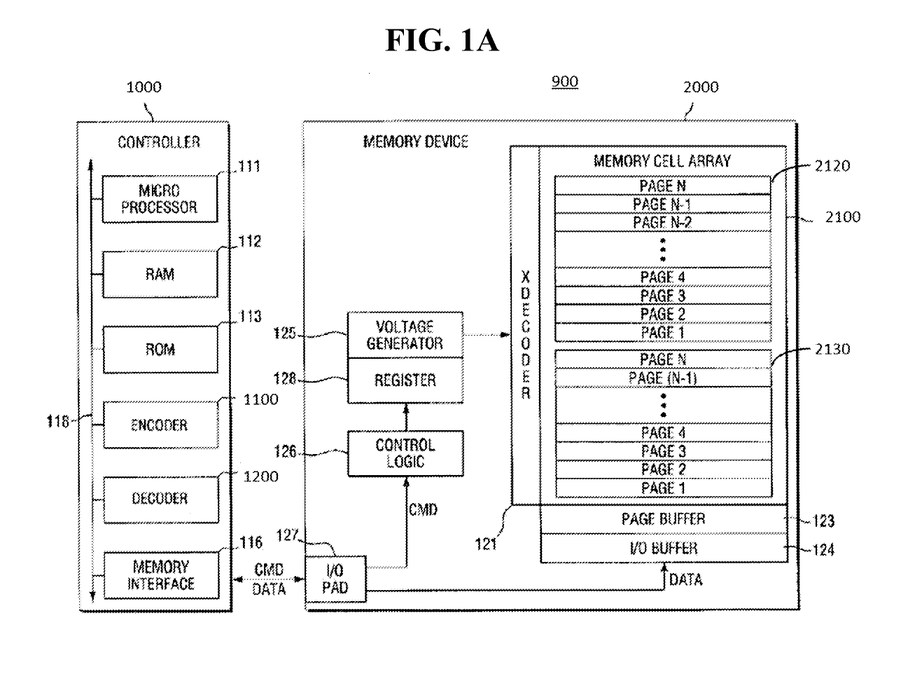

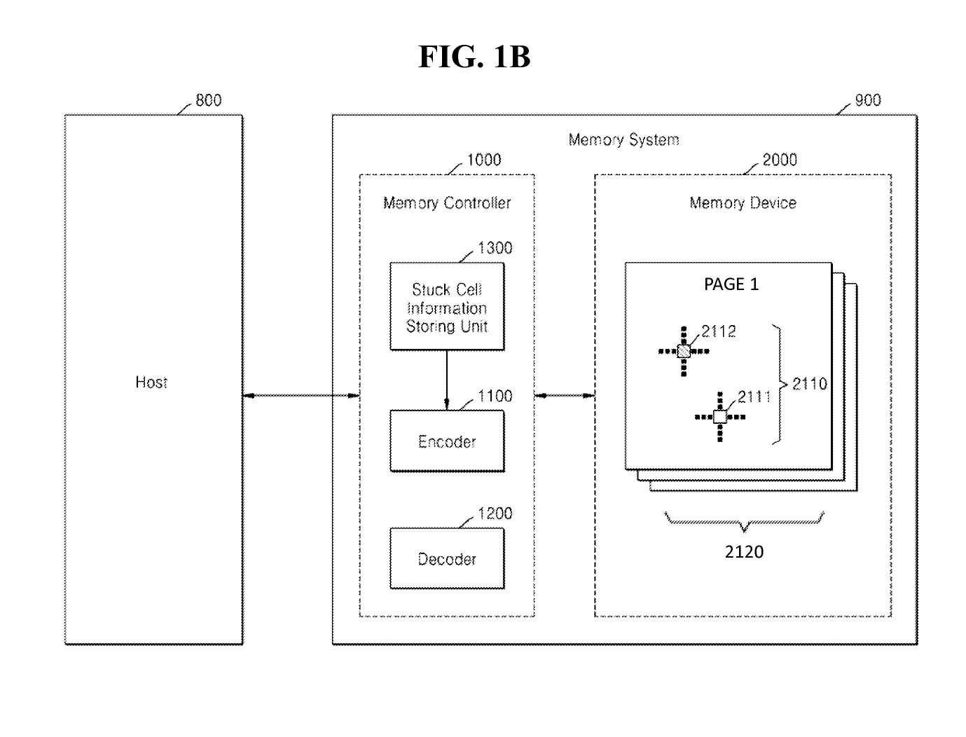

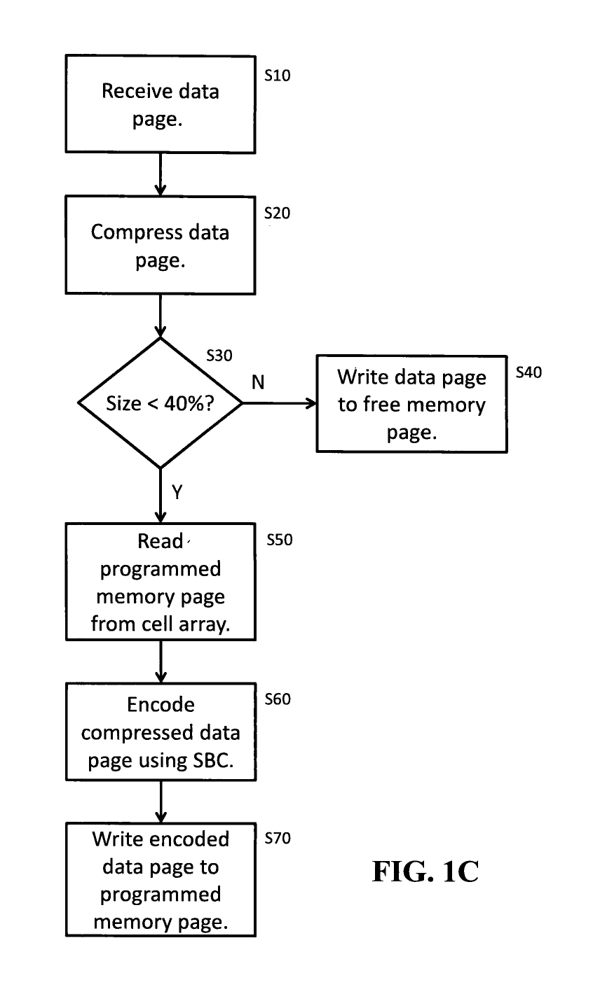

FIG. 1A is a block diagram of a memory system to which a memory according to some embodiments of the present inventive concept is applied. Referring to FIG. 1A, the memory system 900 includes the memory controller 1000 and a nonvolatile memory device 2000.

The nonvolatile memory device 2000 may be, but is not limited to, a flash memory device, a NAND flash memory device, a phase change RAM (PRAM), a ferroelectric RAM (FRAM), a magnetic RAM (MRAM), etc. According to at least one example embodiment of the inventive concepts, the nonvolatile memory device 2000 may include a plurality of NAND flash memory devices. The nonvolatile memory device 2000 may have a planar structure or a three-dimensional (3D) memory cell structure with a stack of memory cells.

The nonvolatile memory device 2000 may include a memory cell array 2100, an X decoder 121, a voltage generator 125, an input/output (I/O) pad 127, an I/O buffer 124, a page buffer 123, and a control logic 126.

The memory cell array 2100 includes a plurality of word lines W/L and a plurality of bit lines B/L. Each memory cell may be implemented as a memory cell having a floating gate or a charge storage layer such as a charge trapping layer.

The memory cell array 2100 may include a plurality of blocks and a plurality of pages. One block includes a plurality of pages. A page may be a unit of program and read operations, and a block may be a unit of erase operation. For example, the memory cell array 2100 includes a first block 2120 and a second block 2130. As is illustrated n FIG. 1A, the first block 2120 includes pages 1−N, and the second block 2130 includes pages 1−N, where N is a positive integer greater than 1.

The control logic 126 controls the overall operation of the nonvolatile memory device 2000. When receiving a command CMD from the memory controller 1000, the control logic 126 interprets the command CMD and controls the nonvolatile memory device 2000 to perform an operation (e.g., a program operation, a read operation, a read retry operation, or an erase operation) according to the interpreted command CMD.

The X decoder 121 is controlled by the control logic 126 and drives at least one of the word lines W/L in the memory cell array 2100 according to a row address.

The voltage generator 125 is controlled by the control logic 126 to generate one or more voltages required for a program operation, a read operation or an erase operation and provide the generated voltages to one or more rows selected by the X decoder 121.

A register 128 is a space in which information input from the memory controller 1000 is stored and may include a plurality of latches. For example, the register 128 may group read voltage information and store the information in the form of a table.

The page buffer 123 is controlled by the control logic 126 and operates as a sense amplifier or a write driver according to an operation mode (e.g., a read operation or a program operation).

The I/O pad 127 and the I/O buffer 124 may serve as I/O paths of data exchanged between an external device, e.g., the memory controller 1000 or a host and the nonvolatile memory device 2000.

The memory controller 1000 may include a microprocessor 111, a read-only memory (ROM) 113, a random access memory (RAM) 112, a encoder 1100, an decoder 1200, a memory interface 116, and a bus 118. The elements 111 through 116 of the memory controller 1000 may be electrically connected to each other through the bus 118.

The microprocessor 111 controls the overall operation of the memory system 900 including the memory controller 1000. When power is supplied to the memory system 900, the microprocessor 111 drives firmware (stored in the ROM 113) for operating the memory system 900 on the RAM 112, thereby controlling the overall operation of the memory system 900.

While a driving firmware code of the memory system 900 is stored in the ROM 113, one or more example embodiments of the inventive concepts are not limited thereto. The firmware code can also be stored in a portion of the nonvolatile memory device 2000 other than the ROM 113. Therefore, the control or intervention of the microprocessor 111 may encompass not only the direct control of the microprocessor 111 but also the intervention of firmware which is software driven by the microprocessor 111.

The RAM 112, which is a memory serving as a buffer, may store an initial command, data, and various variables input from the host or data output from the nonvolatile memory device 2000. The RAM 112 may store data and various parameters and variables input to and output from the nonvolatile memory device 2000.

The memory interface 116 may serve as an interface between the memory controller 1000 and the nonvolatile memory device 2000. The memory interface 116 is connected to the I/O pad 127 of the nonvolatile memory device 2000 and may exchange data with the I/O pad 127. In addition, the memory interface 116 may create a command suitable for the nonvolatile memory device 2000 and provide the created command to the I/O pad 127 of the nonvolatile memory device 2000. The memory interface 116 provides a command to be executed by the nonvolatile memory device 2000 and an address ADD of the nonvolatile memory device 2000.

As will be discussed in greater detail below with referenced to FIGS. 1B-13, the encoder 1100 may perform stuck bit code (SBC) encoding, and the decoder 1200 may perform SBC decoding. Further, according to at least one example embodiment of the inventive concepts, the decoder 1200 may be an error correcting code (ECC) decoder, and the encoder 1100 may be an ECC encoder. According to at least one example embodiment of the inventive concepts, the decoder 1200 and the encoder 1100 perform error bit correction. The encoder 1100 may generate data added with a parity bit by performing error correction encoding on data provided to the nonvolatile memory device 2000. The parity bit may be stored in the nonvolatile memory device 2000.

The decoder 1200 may perform error correction decoding on output data, determine whether the error correction decoding is successful based on the result of the error correction decoding, and output an instruction signal based on the determination result. Read data may be transmitted to the decoder 1200, and the decoder 1200 may correct error bits of the data using the parity bit. When the number of error bits exceeds a limit of error bits that can be corrected, the decoder 1200 cannot correct the error bits, resulting in error correction failure. The encoder 1100 and the decoder 1200 may perform error correction using, for example, low density parity check (LDPC) code, BCH code, turbo code, Reed-Solomon code, convolution code, recursive systematic code (RSC), or coded modulation such as trellis-coded modulation (TCM) or block coded modulation (BCM).

Each of the encoder 1100 and the decoder 1200 may include an error correction circuit, system or device.

When a page of NAND flash memory becomes obsolete, by becoming, for example, invalid, the obsolete page may be erased along with the rest of the block upon which the obsolete page is located in accordance with known garbage collection processes. Once the block is erased, new data can be programmed in the previously obsolete page. However, the process of erasing a block of NAND flash memory may damage the cells of the bock being erased. For example, an erase operation may cause damage to oxide layers of channels of the flash memory cells in the block being erased, thus deteriorating the reliability of the erased block. As is discussed above, a number of erasure operations may increase as a result of write amplification. One way to reduce the effects of write amplification is to use data compression before programming data into NAND flash memory cells. As a result of data compression, a number of sectors written per block of NAND flash memory is increased in comparison to uncompressed data. Accordingly, as a result of data compression, when sectors become invalid, fewer blocks are erased.

According to at least one example embodiment of the inventive concepts, a number of erase operations performed on a NAND flash memory device may be further decreased by reusing already-programmed memory pages, without first erasing the memory pages. The already-programmed memory pages may be reused by treating programmed memory cells among the already-programmed memory pages as stuck bits and encoding write data using SBC encoding.

FIG. 1B is a diagram for explaining stuck bits with respect to the memory system 900 according to at least one example embodiment of the inventive concepts.

As shown in FIG. 1B, the memory system 900 may communicate with a host 800 in compliance with a protocol. For example, the memory system 900 may support protocols including advanced technology attachment (ATA) interface, serial advanced technology attachment (SATA) interface, parallel advanced technology attachment (PATA) interface, universal serial bus (USB) or serial attached small computer system (SAS) interface, small computer system interface (SCSI) interface, embedded multimedia card (EMMC) interface, and universal flash storage (UFS) interfaced. However, the above-stated interfaces are merely examples, and example embodiments of inventive concepts are not limited thereto.

The memory controller 1000 may receive a request from the host 800 outside the memory system 900, and may transmit a response to the request to the host 800.

As shown in FIG. 1B, the first memory block 2120 may include a plurality of memory cells 2110 arranged in an array shape. Each one of the memory cells 2110 is capable of storing the smallest unit of data stored in the memory device 2000 and may have different states according to data stored therein. The memory device 2000 may write data by changing a state of the memory cells 2110 and may output data according to the state of the memory cells 2110. Data corresponding to the state of one of the memory cells 2110 is referred to as a value of the memory cell.

Each of the memory cells 2110 may have two or more different states, and the number of bits of data that may be stored in each of the memory cells 2110 may be determined based on the number of states each of the memory cells 2110 may have. For example, in case of a flash memory, the memory cell 2110 may include a single level cell (SLC) capable of storing 1-bit data or a multi level cell (MLC) capable of storing 2-bit (or more) data, according to a distribution of threshold voltages of a transistor included in the memory cell 2110. Hereinafter, it is assumed that the memory cell 2110 may have a value of “0” or “1” and is capable of storing 1-bit data. However, example embodiments of inventive concepts are not limited thereto.

As shown in FIG. 1B, using PAGE 1 of the first block 2120 as an example, the cell array 2100 may include stuck cells 2112, whose states may not be changed through an additional program operation. For example, in the case of SLC flash memory cells, a memory cell having a programmed state (e.g., a state corresponding to a value of ‘0’) is considered a stuck cell because such a cell is currently programmed to (i.e., “stuck” at) a highest threshold voltage state, and thus, generally cannot be changed to a different state without a memory block erasure operation. As is also shown in FIG. 1B, the cell array 2100 may also include non-stuck memory cells 2111, whose states may still be changed as a result of a programming operation. For example, in the case of SLC flash memory cells, a memory cell having an erase state (e.g., a state corresponding to a value of “1”) is considered a non-stuck cell because such a cell is not currently programmed to a highest threshold voltage state, and thus, generally can be changed to a different state through one or more additional program operations.

The memory cells 2110 may become non-stuck cells 2111 or stuck cells 2112 as a result of data programming and/or erasure operations. For example, in the example shown in FIG. 1B, PAGE 1 of the first block 2120 represents a memory page that currently stores data as a result of a programming operation having been performed on the memory page. For example, when PAGE 1 includes SLC memory cells, the data programmed into PAGE 1 may include a series of values each of which is a “0” or a “1”. Accordingly, the data stored in PAGE 1 of the first block 2120 is such that the value “0” is stored in the stuck cells 2112 of PAGE 1, and the value “1” is stored in the non-stuck cells 2111 of PAGE 1.

In addition to being formed as a result of a data programming operation, other ways one or more of the stuck cells 2112 may be formed include defects caused by a manufacturing process of the memory device 2000, abnormal electric signals applied from outside, or an end-of-life of the memory cell 2100.

As shown in FIG. 1B, in addition to the encoder 1100, and the decoder 1200, the memory controller 1000 may include a stuck cell information storing unit 1300. The stuck cell information storage unit may be implemented by a storage circuit within the memory controller 1000. For example, the stuck cell information storing unit 1300 may be implemented as at least a portion of the RAM 112 illustrated in FIG. 1A. According to at least one example embodiment of the inventive concepts, the stuck cell information storing unit 1300 may store information regarding the stuck cells 2112 included in the cell array 2100 of the memory device 2000. For example, the stuck cell information storing unit 1300 may store the coordinates and the values of the stuck cells 2112 included in the cell array 2100. Detailed descriptions thereof will be given below.

The encoder 1100 may receive stuck cell information from the stuck cell information storing unit 1300 and may generate a code word by encoding data based on the received stuck cell information. According to at least one example embodiment of the inventive concepts, the encoder 1100 and the decoder 1200 may share encoding information (e.g., encoding matrix G) used for encoding data. In other words, the encoder 1100 may add encoding information to the header of a code word, and the decoder 1200 may decode the code word by using the encoding information added to the header.

The encoder 1100 and the decoder 1200 may be embodied hardware, firmware, hardware executing software or any combination thereof included in the memory controller 1000.

When the encoder 1100 and the decoder 1200 are hardware, such hardware may include one or more Central Processing Units (CPUs), digital signal processors (DSPs), application-specific-integrated-circuits (ASICs), field programmable gate arrays (FPGAs) computers or the like configured as special purpose machines to perform the functions of the encoder 1100 and the decoder 1200. CPUs, DSPs, ASICs and FPGAs may generally be referred to as processors and/or microprocessors.

In the event that the encoder 1100 and the decoder 1200 are implemented by one or more processors executing software, the one or more processors are configured as special purpose machines to execute the software to perform the functions described herein with respect to the encoder 1100 and the decoder 1200. In such an embodiment, the controller 1000 may include one or more Central Processing Units (CPUs), digital signal processors (DSPs), application-specific-integrated-circuits (ASICs), field programmable gate arrays (FPGAs) computers.

Furthermore, although FIGS. 1A and 1B show that the memory controller 1000 includes the independent encoder 1100 and the independent decoder 1200, the encoder 1100 and the decoder 1200 may be embodied as a single element.

According to at least one example embodiment, new write data can be programmed onto an already-programmed memory page (e.g., PAGE 1 of the first block 2120) without performing an erase operation, despite the presence of stuck cells 2112 whose states (and thus, values) cannot be changed through programming.

For example, according to at least one example embodiment of the inventive concepts, a data page which is compressed to less than, for example, 40% of an original size of the data page can be written upon an already-programmed physical memory page, where the number of data values having the value “1” stored in the already-programmed memory page is about half the memory page. A tool that enables writing data on to an already programed physical memory page is coding for stuck cells (i.e, SBC). Using SLC NAND flash memory cells as an example, a cell can only be programmed to a higher state, and values of a random data page of size N contain roughly N/2 1's (where the remaining N/2 values of the data page would be 0's), N being a positive integer greater than 1. Suppose that a bit can only be changed (i.e., through programming) from 1 to 0. In that case, N/2 bits (on average) can deliver information if the positions of the N/2 bits are known both to the encoder and decoder. For example, the encoder could simply skip cells with values 0 (i.e., stuck cells), and program only the cells whose current value is 1 (i.e., non-stuck cells); and the decoder could follows the same route (if the decoder knows the positions of zeros in the previous programmed page).

Results from coding theory reveal that even when a decoder is not aware of the positions of the stuck cells, a coding scheme exists which enables, for very long block lengths, transmitting N/2 information bits over such channel, with arbitrarily low encoding failure.

Assume for simplicity an SLC NAND flash with 64 pages per block. U.S. application Ser. No. 14/542,828 entitled “Method and Apparatus for Encoding and Decoding Data in Memory System”, the entire contents of which are hereby incorporated by reference, discloses an efficient encoding and decoding scheme which approach asymptotically the capacity of the stuck bit channel.

For example, using a simple regular code with 3 ones in a row, asymptotic stick rate of 0.43 (out of 1) can be achieved. Equivalently, for a stick rate of 50% (as is our case with 50% 0's in a page) an information rate of 0.42 (out of 1) can be stored. For N=2¹⁶, rates of up to 40% (i.e., data compressed to be equal to or less that 40% of its original size) can be supported using this simple code, and a higher rate (e.g., data compressed to be equal to or less than up to 45% of its original size) for more sophisticated codes. Hence, if a source encoder compresses a page by more than 60%, the compressed page can be stored over an already programmed (but invalid) page, using a rate 0.4 stuck bit code. A method of programming data into an already-programmed memory page according to at least one example embodiment of the inventive concepts will now be discussed in greater detail below with reference to FIG. 1C. The term “stick rate” refers to an average ratio of stick bits relative to a total number of bits in a group of bits. The term stick rate may be user to model a channel in which SBC is used. For example, for a channel where every bit has a (independent) probability Ps to be stuck, the average ratio of stuck bits (i.e., the stick rate) in the channel will be Ps. Asymptotically, as a block length tends to infinity, the real ratio of stick bits will not deviate significantly from that average value Ps. Rate 0.4 code means that the ratio of information bits to overall code size is 0.4 (e.g., out of 1).

FIG. 1C is a flowchart showing a method programming data into an already-programmed memory page according to at least one example embodiment of the inventive concepts.

Referring to FIG. 1C, in step S10 the controller 1000 receives a data page. For example, in step S10, the controller 1000 may receive, from the host 800, a page of data to be written to the memory device 2000. According to at least one example embodiment of the inventive concepts, the controller 1000 may store a size of the data page received in step S10. Operations described herein as being performed by the controller 1000 may be controlled, for example, by the microprocessor 111 illustrated in FIG. 1A.

In step S20, the controller 1000 compresses the data page. For example, according to at least one example embodiment of the inventive concepts, the controller 1000 may perform any known compression operation on the data page received in step S10 in order to reduce a size of the data page, so as to generate a compressed data page. According to at least one example embodiment, the compression operation may be performed by the encoder 1100. According to at least one example embodiment, the controller 1000 may store a size of the compressed data page generated by the controller in step S20.

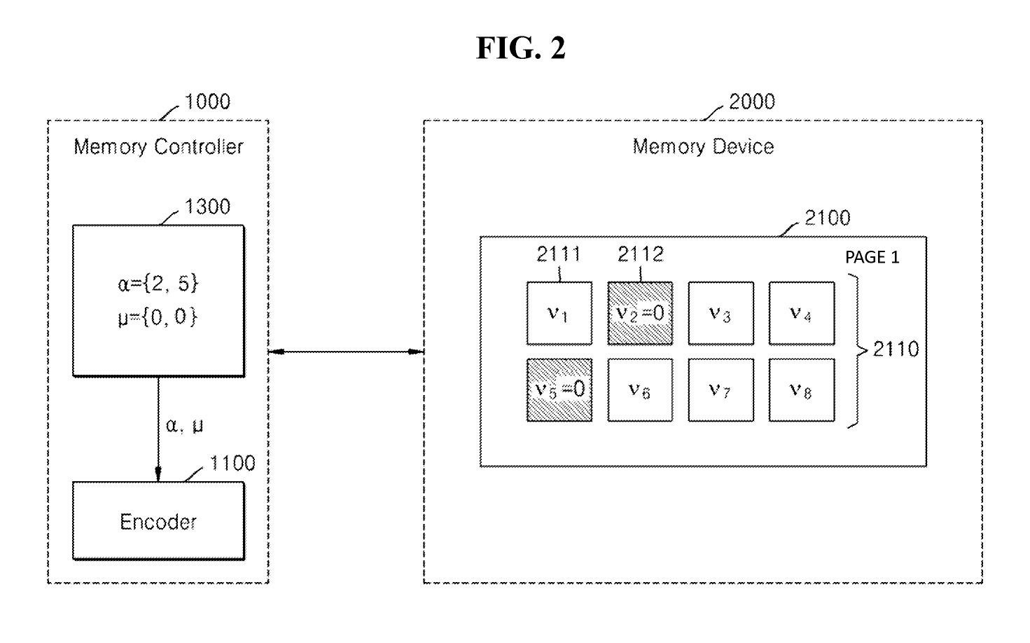

In step S30, the controller 1000 determines whether or not a size of the compressed data page generated in step S20 is less than 40% of a size of the data page received in step S10. For example, the microprocessor 111 may compare a size of the compressed data page generated in step S20 to an original size of the data page received in step S10 and determine whether or not the compression operation performed in step S20 reduced the original size by more than 60%. Though 40% is used as an example size threshold in FIG. 2, the size threshold may have a value other than 40%. For example, the size threshold used in step S30 may be chosen in accordance with the preference of a manufacturer or operator of the controller 1000 and/or memory system 900 can choose an example.

If, in step S30, the controller 1000 determines the size of the compressed data page generated in step S20 is not less than 40% of a size of the data page received in step S10, the controller 1000 proceeds to step S40.

In step S40, the controller 1000 writes the data page to a free memory page of the memory cell array 2100. For example, the microprocessor 111 may generate a write command for controlling the memory device 2000 to write the data page to a free memory page of the memory cell array 2100, and send the generated write command to the memory device 2000 via the memory interface 116, thereby controlling the memory device to write the data page to the free memory page of the memory cell array 2100. According to at least one example embodiment of the inventive concepts, a free memory page is a page to which no data has been written, or, alternatively, a page the memory cells of which are currently in an erase state (e.g., a page of memory cells storing a value of ‘1’ if the memory cells are SLC memory cells). According to at least one example embodiment, the data page written to the memory cell array 2100 in step S40 may be the data page received in step S10 in an uncompressed state or, alternatively, a compressed state (e.g., the compressed data page generated in step S20).

If, in step S30, the controller 1000 (e.g., the processer 111) determines the size of the compressed data page generated in step S20 is less than 40% of a size of the data page received in step S10, the controller 1000 proceeds to step S50.

In step S50, the controller 1000 reads values stored in a programmed memory page of the memory cell array 2100. For example, the microprocessor 111 may generate a read command for controlling the memory device 2000 to output the values stored in a programmed memory page of the memory cell array 2100, send the generated read command to the memory device 2000 via the memory interface 116, and receive the data stored in the programmed memory page from the memory device 2000, in response to the generated read command. According to at least one example embodiment of the inventive concepts, a programmed memory page is a memory page of the memory cell array 2100 to which data has been written, where the written data has not yet been erased. One example of a programmed memory page is an invalid page. An invalid page is a physical memory page to which data has been written, where the written data has become obsolete as a result of a subsequent write operation. For example, according to at least one example embodiment of the inventive concepts, when the physical memory page corresponding to a logical memory page is changed from a first physical memory page to a second physical memory page as a result of new data being written to the logical memory page over old data previously written to the logical memory page (and the first physical memory page), the new data is written to the second physical memory page. As a result of the new data begin written to the second physical memory page, the old data currently stored in the first physical memory page becomes obsolete, and thus, the first physical memory page becomes invalid. According to at least one example embodiment of the inventive concepts, already-programmed PAGE 1 of the first block 2120 illustrated in FIGS. 1A and 1B is an invalid physical memory page and, in step S50, the controller 1000 reads the values stored in an invalid physical memory page (e.g., PAGE 1 of the first block 2120 illustrated in FIGS. 1A and 1B).

Further, as will be discussed in greater detail below with reference to FIG. 2, according to at least one example embodiment of the inventive concepts, in step S50, the memory controller 1000 may generate SC_INFO including information regarding coordinates of stuck cells and information regarding values of the stuck cells.

FIG. 2 is a diagram showing an example of the stuck cell information storing unit 1300 according to at least one example embodiment of the inventive concepts. FIG. 2 illustrates a portion of the first page PAGE 1 of the first block 2120 of the memory cell array 2100. The stuck cell information storing unit 1300 may store information regarding stuck cells included in the cell array 2100. For example, as shown in FIG. 2, first page PAGE 1 of the first block 2120 of the cell array 2100 may include the eight memory cells 2110, and two from among the eight memory cells 2110 may be stuck cells. The eight memory cells 2110 may have coordinates 1 through 8, respectively, and the coordinates of the memory cells 2110 may be addresses of the memory cells 2110.

As shown in FIG. 2, when the eight memory cells 2110 have values v₁ through v₈, respectively, data stored in the cell array 2100 may be expressed as a column vector v=[v₁ . . . v₈]^{T}. However, as shown in FIG. 2, when the memory cells respectively corresponding to the coordinates 2 and 5 are stuck cells and both have fixed values of 0, values v₂ and v₅ of the column vector v stored in the cell array 2100 may be expressed as a column vector v=[v₁ 1 v₃ v₄ 1 v₆ v₇ v₈]^{T}.

According to at least one example embodiment of the inventive concepts, in step S50, the stuck cell information storing unit 1300 may store side information α regarding coordinates of stuck cells included in the cell array 2100 and side information μ regarding values of the stuck cells. For example, in case of the cell array 2100 shown in FIG. 2, the stuck cell information storing unit 1300 may store side information α={2, 5} as coordinates of stuck cells and may store side information μ={0,0} as values of the stuck cells corresponding to the coordinates. Further, the information storing unit 1300 may generate the SC_INFO including information regarding coordinates of stuck cells and information regarding values of the stuck cells, based on side information α and μ stored in the information storing unit 1300.

In step S60, the memory controller S60 encodes the compressed data page generated in step S20 using SBC. For example, in accordance with control signals received from the microprocessor 111, the encoder 1100 may receive the SC_INFO from the information string unit 1300 and encode the compressed data page based on the SC_INFO to generate a code word DATA_CW. For example, in step S60, the encoder 1100 of FIGS. 1A and 1B may receive the SC_INFO including side information α and μ from the stuck cell information storing unit 1300, encode the compressed data based on the side information α and μ, and generate a column vector v corresponding to data to be stored in the cell array 2100. The column vector v generated by the encoder 1100 may include vector entries v₂=0 and v₅=0.

Referring to FIGS. 1 and 2, when the cell array 2100 includes n memory cells 2110 and t memory cells 2110 from among the n memory cells 2110 are the stuck cell 2112 (n>t≧0), the side information α regarding coordinates of the stuck cells 2112, the side information μ regarding values of the stuck cells 2112, and a column vector v corresponding to data stored in the cell array 2100 may be expressed as shown below.

v=[v₁ . . . vₙ]^{T}εFⁿ(F=GF(2))

α={α(1), . . . ,α(t)}(α(1)< . . . <α(t))

μ={μ(1), . . . ,μ(t)}

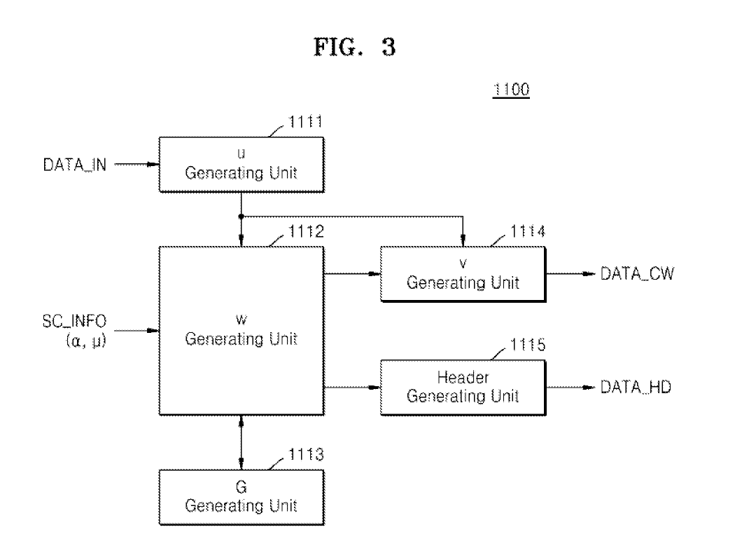

v_{α(j)}=μ(j)(1≦j≦t)

where G is an encoding matrix generated by the encoder 1100. The structure of the encoder 1100 will now be discussed in greater detail below with reference to FIG. 3.

FIG. 3 is a schematic block diagram showing the structure of the encoder 1100 according to at least one example embodiment of the inventive concepts. According to at least one example embodiment of the inventive concepts, the encoder 1100 may include a first vector generating unit, a second vector generating unit, a third vector generating unit, a matrix generating unit, and a header generating unit. For example, FIG. 3 shows an embodiment in which the first vector generating unit is a u generating unit 1111, the second vector generating unit is a w generating unit 1112, the third vector generating unit is a v generating unit 1114, and the matrix generating unit is a G generating unit 1113.

The encoder 1100 may receive input data DATA_IN and stuck cell information SC_INFO and may generate and output code word DATA_CW and header DATA_HD. The input data DATA_IN may include data the host 800 requested the memory system 900 to write, that is, user data and metadata generated by the memory controller 1000 to manage the memory device 2000. According to at least one example embodiment of the inventive concepts, DATA_IN illustrated in FIG. 3 is the data received in step S20 (illustrated in FIG. 1C) in uncompressed or, alternatively, compressed form. Furthermore, the stuck cell information SC_INFO received by the encoder 1100 from the stuck cell information storing unit 1300 may include the side information α regarding coordinates of stuck cells and side information μ regarding values of the stuck cells.

The encoder 1100 may generate the code word DATA_CW such that the code word DATA_CW may include values of stuck cells 2112 at addresses corresponding to coordinates of the stuck cells 2112. Furthermore, the encoder 1100 may generate the header DATA_HD including encoding information regarding the code word DATA_CW, and the header DATA_HD may be stored in the memory controller 1000 or the memory device 2000 separately from the code word DATA_CW.

According to at least one example embodiment of the inventive concepts as shown in FIG. 3, the encoder 1100 may include the u generating unit 1111, the w generating unit 1112, the G generating unit 1113, the v generating unit 1114, and a header generating unit 1115. The u generating unit 1111 may receive the input data DATA_IN and generate a column vector u=[u₁ . . . uₙ₋ₛ]^{T} (0≦t≦s<n). The u generating unit 1111 may select data to be stored in the cell array 2100 including the n memory cells 2110 from among the input data DATA_IN and generate the column vector u. Since the cell array 2100 includes t stuck cells, the u generating unit 1111 is unable to store data in all of the n memory cells 2110. Therefore, the u generating unit 1111 may generate the column vector u including n-s entries (s≧t). For example, in the embodiment shown in FIG. 2, the u generating unit 1111 may select data corresponding to a column vector u=[u₁ u₂ u₃ u₄ u₅]^{T} including five entries from among the input data DATA_IN and output the column vector u (s=3).

The G generating unit 1113 may generate the encoding matrix G. The encoding matrix G is an n×n matrix including n rows and n columns and may be used for generating a column vector v. The G generating unit 1113 may receive signals from the w generating unit 1112, generate a new encoding matrix G based on the signals, and output the new encoding matrix G. The G generating unit 1113 may generate an encoding matrix G randomly or pseudo-randomly. For example, the G generating unit 1113 may generate an encoding matrix G by combining at least one from among matrixes stored in a memory randomly or pseudo-randomly. Detailed descriptions thereof will be given below.

The w generating unit 1112 may receive the stuck cell information SC_INFO from the stuck cell information storing unit 1300, may receive the column vector u from the u generating unit 1111, and may receive the encoding matrix G from the G generating unit 1113. A column vector w generated by the w generating unit 1112 is auxiliary data based on stuck cells included in the cell array 2100, where the column vector w may be added to the column vector u generated by the u generating unit 1111 and may be used for generating the column vector v. The column vector w generated by the w generating unit 1112 may be expressed as w=[w₁ . . . wₛ]^{T}. The s entries w₁ through wₛ included in the column vector w may be determined based on the column vector u, the side information α, the side information μ, and the encoding matrix G that are received by the w generating unit 1112. If the w generating unit 1112 is unable to determine s entries w₁ through wₛ based on the column vector u, the side information α, the side information μ, and the encoding matrix G, the w generating unit 1112 may receive a new encoding matrix G from the G generating unit 1113 and determine s entries w₁ through wₛ by using the new encoding matrix G. Furthermore, the w generating unit 1112 may generate and output a label for the encoding matrix G used for generating the column vector w. The label is for the decoder 1200 to recognize the encoding matrix G used by the encoder 1100.

The v generating unit 1114 may receive the column vector u from the u generating unit 1111 and may receive the column vector w from the w generating unit 1112. Furthermore, the v generating unit 1114 may receive the encoding matrix G used by the w generating unit 1112 to generate the column vector w from the w generating unit 1112. The v generating unit 1114 may generate the code word DATA_CW by using the column vectors u and w and the encoding matrix G, where the code word DATA_CW may be expressed as a column vector v=[v₁ . . . vₙ]^{T}. In detail, the v generating unit 1114 may generate a column vector x by concatenating the column vector w with the column vector u and may generate the column vector v by multiplying the encoding matrix G by the column vector x.

The header generating unit 1115 may receive the label of the encoding matrix G and s from the w generating unit 1112 and may generate the header DATA_HD. The header DATA_HD generated by the header generating unit 1115 may include information that may be used for the decoder 1200 to decode the code word DATA_CW, and the decoder 1200 may decode the code word DATA_CW by using the information included in the header DATA_HD. For example, the decoder 1200 may recognize the encoding matrix G used for encoding the code word DATA_CW based on the label of the encoding matrix G included in the header DATA_HD and may generate a column vector x′ by multiplying the code word DATA_CW by an inverse matrix of the encoding matrix G. Furthermore, the decoder 1200 may extract a column vector u′ included in the column vector x′ by using s and may restore data based on the column vector u′.

Returning to FIG. 1C, in step S70, the memory controller 1000 writes the encoded data page to the already-programmed memory page. For example, according to at least one example embodiment of the inventive concepts, in step S70, the memory controller 1000 writes the code word DATA_CW, generated by the encoder 1100 in step S60, to PAGE 1 of the first memory block 2120 of the memory cell array 2100. For example, the microprocessor 111 may generate a write command for controlling the memory device 2000 to write the code word DATA_CW to PAGE 1 of the first memory block 2120, and send the generated write command to the memory device 2000 via the memory interface 116, thereby controlling the memory device 2000 to write the code word DATA_CW to PAGE 1 of the first memory block 2120. According to at least one example embodiment of the inventive concepts, in step S70, the controller 1000 may also store the header DATA_HD generated by the header generating unit 1115 in step S60. For example, the header DATA_HD generated by the header generating unit 1115 may be stored in a storage space accessible by the encoder 1100 and the decoder 1200 separately from the code word DATA_CW. For example, the header DATA_HD may be stored in a storage space included in the memory controller 1000 or a cell array included in the memory device 2000. Alternatively, according to at least one example embodiment of the inventive concepts, the generation of the header DATA_HD is omitted from step S60, and the header DATA_HD is not stored in or by the memory controller 1000.

Though FIG. 1C is discussed with respect to an example where the unit by which data is written over already-programmed data is a page, a size of the unit by which data is written over already-programmed data (without erasure) may be any size (e.g., one or more sectors, pages, word lines, or blocks) in accordance with the preferences of a manufacturer and/or operator of the memory system 900.

Additional structures for, and example operations of, the encoder 1100 and the decoder 1200 of FIGS. 1A and 1B, including operations for encoding and decoding information using SBC, are discussed further in U.S. application Ser. No. 14/542,828 entitled “Method and Apparatus for Encoding and Decoding Data in Memory System”, which was previously incorporated herein by reference above.

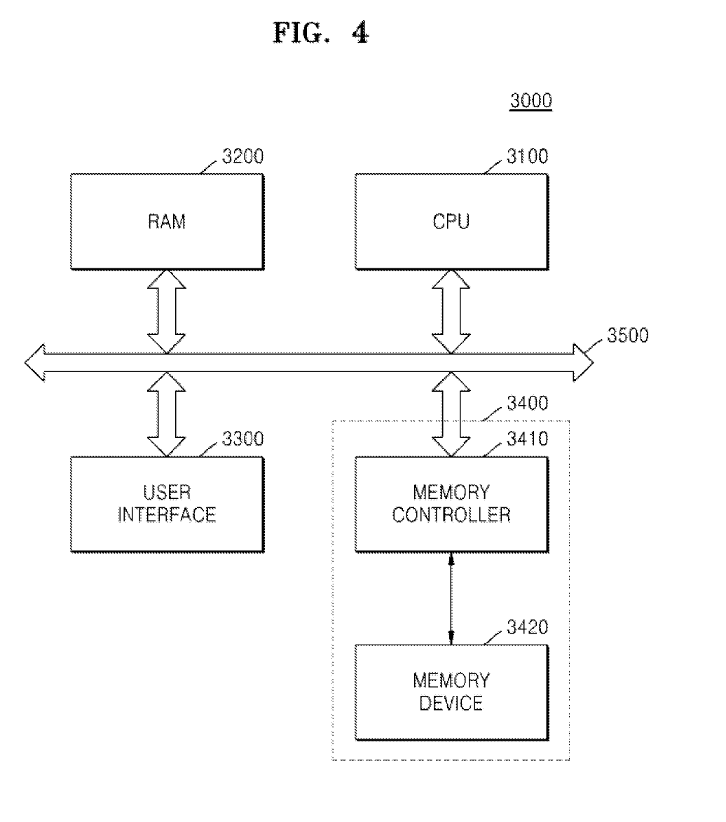

FIG. 4 is a block diagram showing a computer system 3000 including a memory system according to at least one example embodiment of the inventive concepts. The computer system 3000, such as a mobile device, a desktop computer, and a server, may employ a memory system 3400 according to at least one example embodiment of the inventive concepts.

The computer system 3000 may include a central processing unit 3100, a RAM 3200, a user interface 3300, and the memory system 3400, are electrically connected to buses 3500. The host as described above may include the central processing unit 3100, the RAM 3200, and the user interface 3300 in the computer system 3000. The central processing unit 3100 may control the entire computer system 3000 and may perform calculations corresponding to user commands input via the user interface 3300. The RAM 3200 may function as a data memory for the central processing unit 3100, and the central processing unit 3100 may write/read data to/from the memory system 3400.

As in example embodiments of inventive concepts described above, the memory system 3400 may include a memory controller 3410 and a memory device 3420. The memory controller 3410 may include an encoder, a decoder, and a stuck cell information storing unit, the memory device 3420 may include a cell array including a plurality of memory cells, and the cell array may include stuck cells. The encoder may receive information regarding stuck cells from the stuck cell information storing unit, encode data to be stored in the cell array, generate code word, and generate a header corresponding to the code word. The code word generated by the encoder may include values of the stuck cells included in the cell array. The decoder may extract encoding information from the header and decode the data stored in the cell array based on the encoding information.

According to at least one example embodiment of the inventive concepts, the memory controller 3410 and a memory device 3420 may be implemented, respectively. by the memory controller 1000 and a memory device 2000 discussed above with reference to FIGS. 1A-3.

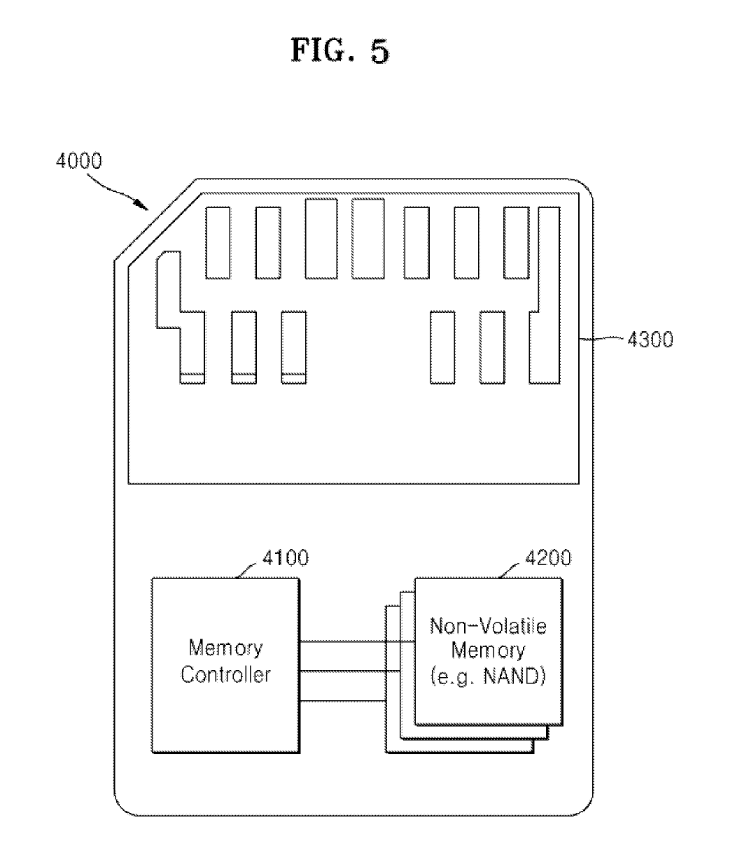

FIG. 5 is a block diagram showing a memory card 4000 according to at least one example embodiment of the inventive concepts. A memory system according to example embodiments of inventive concepts described above may be the memory card 4000. For example, the memory card 4000 may include an embedded multimedia card (eMMC) or a secure digital (SD) card. As shown in FIG. 15, the memory card 4000 may include a memory controller 4100, a non-volatile memory 4200, and a port region 4300. A memory device according to example embodiments of inventive concepts may be the non-volatile memory 4200 shown in FIG. 15.

The memory controller 4100 may include an encoder, a decoder, and a stuck cell information storing unit according to example embodiments of inventive concepts as described above. The encoder and the decoder may perform an encoding method and a decoding method according to example embodiments of inventive concepts, whereas the stuck cell information storing unit may store information regarding stuck cells included in the non-volatile memory 4200. The memory controller 4100 may communicate with an external host via the port region 4300 in compliance with a pre-set protocol. The protocol may be eMMC protocol, SD protocol, SATA protocol, SAS protocol, or USB protocol. The non-volatile memory 4200 may include memory cells which retain data stored therein even if power supplied thereto is blocked. For example, the non-volatile memory 4200 may include a flash memory, a magnetic random access memory (MRAM), a resistance RAM (RRAM), a ferroelectric RAM (FRAM), or a phase change memory (PCM).

According to at least one example embodiment of the inventive concepts, the memory controller 4100 and a memory device 4200 may be implemented, respectively, by the memory controller 1000 and a memory device 2000 discussed above with reference to FIGS. 1A-3.

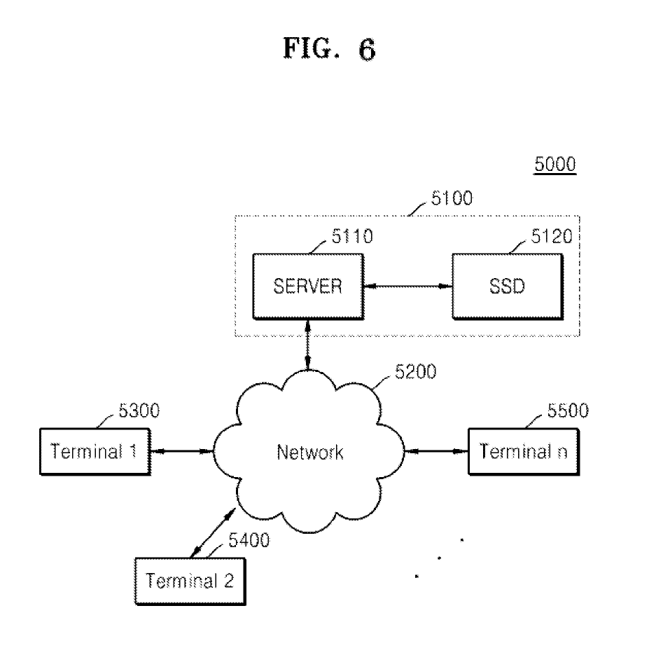

FIG. 6 is a block diagram showing an example network system 5000 including a memory system according to at least one example embodiment of the inventive concepts. As shown in FIG. 16, the network system 5000 may include a server system 5100 and a plurality of terminals 5300, 5400, and 5500 that are connected via a network 5200. The server system 5100 may include a server 5110 for processing requests received from the plurality of terminals 5300, 5400, and 5500 connected to the network 5200 and a SSD 5120 for storing data corresponding to the requests received from the terminals 5300, 5400, and 5500. Here, the SSD 5120 may be a memory system according to at least one example embodiment of the inventive concepts.

According to at least one example embodiment of the inventive concepts, SSD 5120 may be implemented by the memory system 900 discussed above with reference to FIGS. 1A-3.

Meanwhile, a memory system according to example embodiments of inventive concepts may be mounted via any of various packages. For example, a memory system according to at least one example embodiment of the inventive concepts may be mounted via any of packages including package on package (PoP), ball grid arrays (BGAs), chip scale packages (CSPs), plastic leaded chip Carrier (PLCC), plastic dual in-line package (PDIP), die in waffle pack, die in wafer form, chip on board (COB), ceramic dual in-line package (CERDIP), plastic metricquad flat pack (MQFP), thin quad flatpack (TQFP), small outline (SOIC), shrink small outline package (SSOP), thin small outline (TSOP), thin quad flatpack (TQFP), system in package (SIP), multi chip package (MCP), wafer-level fabricated package (WFP), wafer-level processed stack package (WSP), etc.

It should be understood that example embodiments described herein should be considered in a descriptive sense only and not for purposes of limitation. Descriptions of features or aspects within each embodiment should typically be considered as available for other similar features or aspects in other example embodiments.

What is claimed is:

1. A memory controller of a memory system, the memory system including the memory controller and a memory device, the memory controller comprising:
a processor configured to receive write data an control the memory controller; and
an encoder,
the processor being configured to,
receive write data,
read previously programmed data from a first memory page of a memory cell array of the memory device, and
control the encoder to generate encoded data by encoding the write data using stuck bit code (SBC), based on the read previously programmed data,
the previously programmed data being data that has been programmed into the first memory page of the memory cell array and has not been erased;
the processor being configured to write the encoded data to the first memory page without erasing the first memory page.

2. The memory controller of claim 1, wherein the processor is configured such that the first memory page from which the previously programmed data is read is an invalid memory page of the memory cell array.

3. The memory controller of claim 1, wherein the processor is configured to perform a data compression operation on the received write data.

4. The memory controller of claim 3,
wherein the processor is further configured to,
store an original size, and
perform a comparison operation based on a compressed size and the stored original size,
wherein the processor is configured to control the encoder to generate the encoded data and to write the encoded data to the first memory page only when the comparison operation indicates the compressed size is less than a threshold size,
the original size being a size of the received write data before the data compression operation is performed on the write data,
the compressed size being a size of the received write data after the data compression operation is performed on the write data.

5. The memory controller of claim 4, wherein the processor is configured such that, when the comparison operation indicates the compressed size is not less than the threshold size, the processor writes the received write data to a free page of the memory cell array,
the free page being a memory page of the memory cell array to which no data has been written since a most recent erase operation performed on the free page.

6. The memory controller of claim 1, wherein the processor is configured to control the encoder such that the encoded data generated by the encoder is different than the received write data and different than the read previously programmed data.

7. The memory controller of claim 1, further comprising:
a decoder,
wherein the processor is configured to generate read data by reading data stored in the first page after the encoded data is written to the first page,
and the processor is configured to control the decoder to generate decoded data by decoding the read data using SBC.

8. The memory controller of claim 7, wherein the decoder is an error correcting code (ECC) decoder configured to generate the decoded data using SBC and ECC.

9. The memory controller of claim 1, wherein the encoder is an error correcting code (ECC) encoder configured to generate the encoded data using SBC and ECC.

10. The memory controller of claim 1, wherein,
the processor is configured to read the previously programmed data from the first memory page as single level cell (SLC) data, and
the processor is configured to control the encoder to generate the encoded data by encoding the write data using stuck bit code (SBC), based on the read SLC data.

11. The memory controller of claim 1, wherein,
the processor is configured to read the previously programmed data from the first memory page as multi level cell (MLC) data, and
the processor is configured to control the encoder to generate the encoded data by encoding the write data using stuck bit code (SBC), based on the read MLC data.

12. A memory system comprising:
a memory controller; and
a memory device;
the memory controller being configured to,
receive write data,
read previously programmed data from a first page of a memory cell array of the memory device, the previously programmed data being data that has been programmed into the first memory page of the memory cell array and has not been erased,
generate encoded data by encoding the write data using stuck bit code (SBC), based on the read previously programmed data, and
write the encoded data to the first memory page without erasing the first memory page.

13. The memory system of claim 12, wherein the processor is configured such that the first memory page from which the previously programmed data is read is an invalid memory page of the memory cell array.

14. The memory system of claim 12, wherein the memory controller is configured to perform a data compression operation on the received write data.

15. The memory system of claim 14,
wherein the memory controller is further configured to,
store an original size, and
perform a comparison operation based on a compressed size and the stored original size,
wherein the memory controller is configured to generate the encoded data and to write the encoded data to the first memory page only when the comparison operation indicates the compressed size is less than a threshold size,
the original size being a size of the received write data before the data compression operation is performed on the write data,
the compressed size being a size of the received write data after the data compression operation is performed on the write data.

16. The memory system of claim 15, wherein, the memory controller is configured such that, when the comparison operation indicates the compressed size is not less than the threshold size, the memory controller writes the received write data to a free page of the memory cell array,
the free page being a memory page of the memory cell array to which no data has been written since a most recent erase operation performed on the free page.

17. The memory system of claim 12, wherein the memory controller is configured to generate the encoded data such that the encoded data is different than the received write data and different than the read previously programmed data.

18. The memory system of claim 12 wherein, the memory controller is further configured to,
generate read data by reading data stored in the first page after the encoded data is written to the first page, and
generate decoded data by decoding the read data using SBC.

19. The memory system of claim 18, wherein the memory controller is configured to generate the decoded data using SBC and error correcting code (ECC).

20. The memory controller of claim 12, wherein the memory controller is configured to generate the encoded data using SBC and error correcting code (ECC).

21. The memory system of claim 12, wherein,
the memory controller is configured to read the previously programmed data from the first memory page as single level cell (SLC) data, and
the memory controller is configured to generate the encoded data by encoding the write data using stuck bit code (SBC), based on the read SLC data.

22. The memory system of claim 12, wherein,
the memory controller is configured to read the previously programmed data from the first memory page as multi level cell (MLC) data, and
the memory controller is configured to generate the encoded data by encoding the write data using stuck bit code (SBC), based on the read MLC data.
